(19) United States
(12) Patent Application Publication
(10) Pub. No.: US 2026/0324113 A1
(43) Pub. Date: Oct. 15, 2026

(54) SEMICONDUCTOR DEVICE AND METHOD OF MANUFACTURING THE SAME

(71) Applicant: Taiwan Semiconductor Manufacturing Company, Ltd., Hsinchu (TW)

(72) Inventors: Keng-Yu Chou, Kaohsiung City (TW); Cheng-Yu Huang, Hsinchu (TW); Wei-Chieh Chiang, Yuanlin Township (TW); Chun-Hao Chuang, Hsinchu City (TW); Yi-Hsuan Wang, Hsinchu City (TW)

(21) Appl. No.: 19/281,874

(22) Filed: Jul. 28, 2025

Related U.S. Application Data
(60) Provisional application No. 63/787,749, filed on Apr. 12, 2025.

(51) Int. Cl. H10F 39/00

(52) U.S. Cl. CPC H10F 39/8063; H10F 39/024; H10F 39/807

(57) ABSTRACT

A diffuser disposed between a microlens and a photodiode has a structure that redirects incoming light to provide favorable angles for increasing path length through the substrate, and therefore the probability of absorption, for both normally incident light and light angling toward the center of the pixel area from the periphery of the microlens. The diffuser comprises gratings formed from indentation in the semiconductor substrate that contains the photodiode. One of the gratings is disposed in each of four quadrants of an area centered beneath the microlens. Each quadrant has a midline extending radially from the center of the area. The gratings are oriented parallel to the respective midline, and perpendicular to the gratings in adjacent quadrants. The gratings may comprise trenches having V-shaped profiles.

### REFERENCE TO RELATED APPLICATION

This Application claims priority to U.S. Provisional Application No. 63/787,749, filed on Apr. 12, 2025, the contents of which are hereby incorporated by reference in their entirety.

### BACKGROUND

Many modern day electronic devices (e.g., digital cameras, optical imaging devices, etc.) comprise image sensors. An image sensor includes an array of photosensitive areas which are operative as transducers that convert light into electrical charges. Examples of image sensors include charge-coupled device (CCD) image sensors and complementary metal-oxide-semiconductor (CMOS) image sensors. Compared to CCD image sensors, CMOS image sensors are favored due to low power consumption, small size, fast data processing, a direct output of data, and low manufacturing cost. One type of CMOS image sensor is a backside illuminated (BSI) CMOS image sensor.

### BRIEF DESCRIPTION OF THE DRAWINGS

Aspects of the present disclosure are best understood from the following detailed description when read with the accompanying figures. In accordance with standard industry practice, features are not drawn to scale. Moreover, the dimensions of various features within individual drawings may be arbitrarily increased or reduced relative to one-another to facilitate illustration or provide emphasis.

FIG. 1A illustrates a plan view of an embodiment of an image sensor having a diffuser according to the present disclosure.

FIGS. 1B-1D illustrate cross-sectional views of the image sensor of FIG. 1A.

FIG. 2A illustrates a perspective view of a microlens focusing light on a diffuser.

FIGS. 2B-2C illustrates perspective views of light from a microlens interacting with a trench that is part of a diffuser according to the present disclosure.

FIGS. 3-4 illustrate plan views of image sensors with diffusers according to various embodiments.

FIGS. 5A-6B illustrate paired plan and cross-sectional views of image sensors with diffusers according to various embodiments.

FIGS. 7A-9B illustrate plan views of image sensors with diffusers according to various embodiments.

FIGS. 10-18 (with the exception of FIG. 13A-C) illustrate cross-sectional views of an image sensor undergoing manufacture according to a process of the present disclosure.

FIGS. 13A-13C illustrates masks that can be used in the manufacturing process illustrated by FIGS. 10-18.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

Spatially relative terms, such as “beneath,” “below,” “lower,” “above,” “upper”, and the like, may be used herein to describe one element or feature's relationship to another element(s) or feature(s) as illustrated in the figures. These spatially relative terms are intended to encompass different orientations of the device or apparatus in use or operation in addition to the orientation depicted in the figures. The device or apparatus may be otherwise oriented (rotated 90 degrees or at other orientations) and the spatially relative descriptors used herein may be interpreted accordingly. Terms “first”, “second”, “third”, “fourth”, and the like are merely generic identifiers and, as such, may be interchanged in various embodiments. For example, while an element (e.g., an opening) may be referred to as a “first” element in some embodiments, the element may be referred to as a “second” element in other embodiments.

A complementary metal-oxide-semiconductor (CMOS) image sensor includes an array of photodiodes formed within a semiconductor substrate. Incident radiation is detected when absorbed by the substrate, generating electron-hole pairs. A pixel circuit, which includes one of the photodiodes, converts the resulting charge carriers into an electrical signal.

Semiconductor substrates often comprise monocrystalline silicon, primarily due to its low cost and widespread availability in the industry. However, monocrystalline silicon exhibits a relatively low absorption coefficient for near-infrared (NIR) and other long-wavelength radiation. As photodetector pixels continue to shrink, this low absorption becomes increasingly detrimental, resulting in reduced quantum efficiency (QE).

To enhance QE, techniques such as back-side illumination, inter-pixel reflectors, and microlenses are commonly employed. A less prevalent but effective approach involves the use of a diffuser. A diffuser increases the optical path length within the substrate by redirecting incident light, thereby raising the likelihood of photon absorption. Diffusers can be implemented by etching patterns—such as gratings or inverted pyramids—into the back surface of the semiconductor substrate, between the microlens and the photodiode. These etched features are typically filled with materials having a refractive index lower than that of the semiconductor substrate.

Diffusers redirect incoming light across a range of angles, with the resulting angular distribution determined by both the incident light direction and the surface geometry of the diffuser. For example, light entering through the center of a microlens typically strikes the pixel surface at near-normal incidence, while light entering through the periphery of the microlens is generally bent to more oblique angles. Inverted pyramid diffusers are particularly effective at redirecting normally incident rays toward more oblique paths, enhancing absorption. However, they may also deflect already oblique rays (originating from the microlens periphery) into steeper angles, potentially reducing overall absorption efficiency.

The present disclosure provides diffusers configured to redirect incident light in an angular distribution that peaks between approximately 30 and 40 degrees—an angular range found to be particularly effective in enhancing absorption efficiency. The diffusers comprise four gratings, each disposed within one of four quadrants of an area approximately centered beneath a microlens. Within each quadrant, the grating includes one or more trenches that are parallel to one another. Each grating has the same orientation as the grating in the opposite quadrant, and a distinct orientation from the gratings in the adjacent quadrants. The grating orientations differ by 90 degrees between adjacent quadrants. The trenches in each quadrant are approximately parallel to a radian extending from the center of the microlens area into the corresponding quadrant. The radian can be a midline of the quadrant.

In some embodiments, the gratings include trenches and inverted pyramidal features having planar sidewalls. A first group of sidewalls is parallel to one another and parallel to the radian associated with the respective quadrant. A second group of sidewalls, having a different orientation, is also mutually parallel and aligned with the same radian. Each trench includes one sidewall from each group. These repeating geometries establish the grating orientation within each quadrant.

The gratings described herein perform comparably to inverted pyramids in redirecting normally incident light but exhibit superior performance with obliquely incident rays originating from the periphery of the microlens. Whereas related inverted pyramid diffusers can improve quantum efficiency by up to approximately 38%, the diffusers disclosed in the present application have demonstrated quantum efficiency gains of about 45% or more under similar conditions.

In some embodiments, each grating exhibits mirror symmetry with respect to the gratings in adjacent quadrants. In some embodiments, the gratings exhibit 90-degree rotational symmetry about the center of the area beneath the microlens. Additionally, each grating may be symmetric about its respective midline. These symmetrical configurations are typical for gratings that are easily manufactured and have orientation that vary among four quadrants as taught herein to provide enhanced absorption of both normally incident light and light redirected toward the center by the microlens.

In some embodiments, the gratings comprise trenches formed in the semiconductor substrate with V-shaped cross-sectional profiles. Trenches with such profiles demonstrate superior light-capturing capability compared to those with vertical sidewalls or with sloped sidewalls terminating in flat bottoms. The sidewalls can slope to be at angles between about 15 degrees and about 45 degrees from vertical to impart normally incident light with suitable trajectories. In some embodiments, adjacent trenches converge at V-shaped peaks, which further enhance light capture relative to configurations where flat regions separate adjacent indentations.

In some embodiments, the semiconductor substrate has a (100) crystal orientation, and the trenches extend along <110> crystallographic directions. These orientations support the formation of V-shaped trench profiles and enable undercutting beneath a masking layer such that adjacent trenches merge at V-shaped peaks. The trenches can have depths proportional to their widths. In some embodiments, the trenches have depth to width ratios of about 0.7 and sidewalls sloping at about 27 degrees from vertical, which are typical for trenches formed by wet etching of a semiconductor substrate having (100) crystal orientation.

In some embodiments, the diffuser includes gratings disposed within each of four quadrants of an area centered beneath a microlens. Each quadrant has a midline extending radially from the center of the area. The gratings comprise trenches oriented parallel to their respective midlines. In some embodiments, trenches in adjacent quadrants intersect to form L-shaped trenches, with each trench arm aligned at a right angle and contributing to a distinct grating in a different quadrant. The arms of the L-shaped trench generally have equal lengths. In some embodiments, each grating comprises an even number of elements; in other embodiments, an odd number. When the gratings are periodic and include an odd number of elements, the diffuser incorporates a centrally located cross-shaped trench comprising four arms, each forming part of a grating in one of the four quadrants.

Each grating can comprise parallel trenches of varying lengths. In certain embodiments, the longest trenches are positioned near the grating's midline, with trench lengths decreasing progressively toward the sides of the quadrant. In some configurations, the outermost element of each grating is not a trench but a half of an inverted pyramid-shaped indentation formed in the semiconductor substrate. In some embodiments, the diffuser comprises four such inverted pyramid-shaped indentations, corresponding to the outermost elements of the four gratings. These geometries may result from conforming the diffuser to a square footprint, such as that defined by a photodetector pixel area.

In certain embodiments, the indentations that form the gratings are deepest and widest near their respective midlines and become progressively shallower and narrower toward the outer edges of the gratings. As the midlines of the four quadrants intersect at the center of the area underneath the microlens, the deepest and widest trenches converge at the center. Making the indentations deeper at the center of the area underneath the microlens can facilitate light trapping.

In certain embodiments, the indentations forming the diffuser are confined to the central region of the area underneath the microlens. The diffuser may occupy half or less of the area; in some embodiments, one fourth or less; and in other embodiments, one eighth or less. When combined with a microlens that effectively concentrates incoming light onto the central region, limiting the diffuser area in this way can facilitate light trapping and improve absorption efficiency.

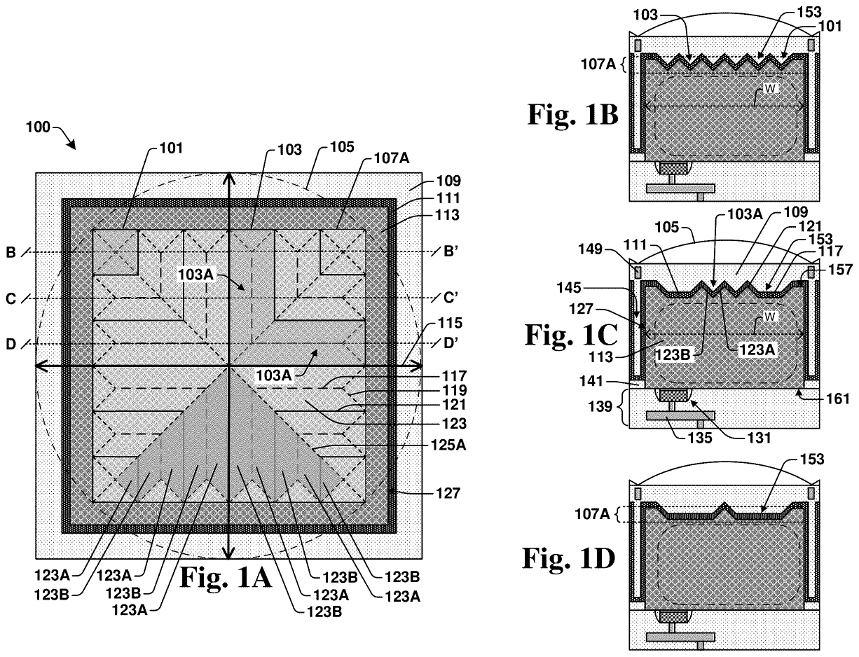

FIG. 1A illustrates a plan view of an image sensor 100 that includes a diffuser 107A located within a pixel area 127 of a semiconductor substrate 113. The pixel area 127 and the diffuser 107A are centered beneath a microlens 105 (or equivalently, the microlens 105 is centered above the pixel area 127 and the diffuser 107A). FIGS. 1B-1D show cross-sectional views taken along lines B-B′, C-C′, and D-D′, respectively, of FIG. 1A. The diffuser 107A comprises four gratings 125A, one of which is labeled and shaded in FIG. 1A for reference. These four gratings 125A are arranged with 90-degree rotational symmetry about the center of the pixel area 127. Each grating 125A includes a set of indentations 153 (see FIGS. 1B-1D) formed in the back side 157 of the semiconductor substrate 113. Some of the indentations 153 are shared between adjoining gratings 125A.

The indentations 153 include four inverted pyramids 101 and eight L-shaped trenches 103, with one of each labeled and shaded in FIG. 1A. Both the trenches 103 and the inverted pyramids 101 have flat sidewalls, referred to as facets 123. The intersections of these facets 123 are illustrated using different line styles: solid lines indicate raised edges (V-shaped peaks 121); dashed lines 117 mark intersections at the bottoms of trenches 103; and short-dashed lines 119 show sloping intersections between facets. Each L-shaped trench 103 has two trench arms 103A, with each arm forming part of a different grating 125A. The trench arms 103A have V-shaped cross-sectional profiles.

The pixel area 127 is a portion of the semiconductor substrate 113 that is bounded by an isolation structure, such as a back-side deep trench isolation (BDTI) structure 145 (see FIG. 1C). A medium refractive index dielectric layer 111 and a low refractive index dielectric layer 109 provide fill for the BDTI structure 145 and extend across the back side 157 to also fill the indentations 153, thereby completing the diffuser 107A. In some embodiments, the BDTI structure 145 includes a metal core (not shown) to enhance reflectivity. Although a BDTI structure is depicted and offers certain advantages, a front-side deep trench isolation (FDTI) structure may be used in its place. Additionally, a back side metal grid 149 may be disposed on the back side 157 above the BDTI structure 145 to further enhance light capture and reduce optical crosstalk.

Each of the gratings 125A exhibits mirror symmetry about a respective midline 115. These midlines 115 extend radially from the center of the pixel area 127, which coincides with the center of the area beneath the microlens 105. Adjacent gratings 125A are separated by additional radial lines, also emanating from this central point. As a result, the diffuser 107A can be conceptually divided into eight sectors by eight radial lines spaced at 45-degree intervals. Each sector contains a portion of a grating that is symmetrical with that of its neighboring sectors, by reflection across the radial line separating them.

The gratings 125A are oriented parallel to their respective midlines 115 such that their trench arms 103A extend parallel to their respective midlines 115. Within each grating 125A, the trench sidewalls comprise facets 123, which include two distinct groups: facets 123A and facets 123B. The facets 123A are parallel to one another and to the midline 115 of the grating. The facets 123B, while oriented differently from facets 123A, are also mutually parallel and aligned with the same midline 115. Together, pairs of facets 123A and 123B form the angled sidewalls of the V-shaped trench arms 103A. This configuration—where the facets 123 of the indentations 153 are parallel to the midline 115, and the midline 115 is a radian extending from the center of the area under the microlens 105—results in a grating orientation that provides consistently oblique angles of light entry into the semiconductor substrate 113, as compared to other diffuser geometries that can be manufactured using related process technologies.

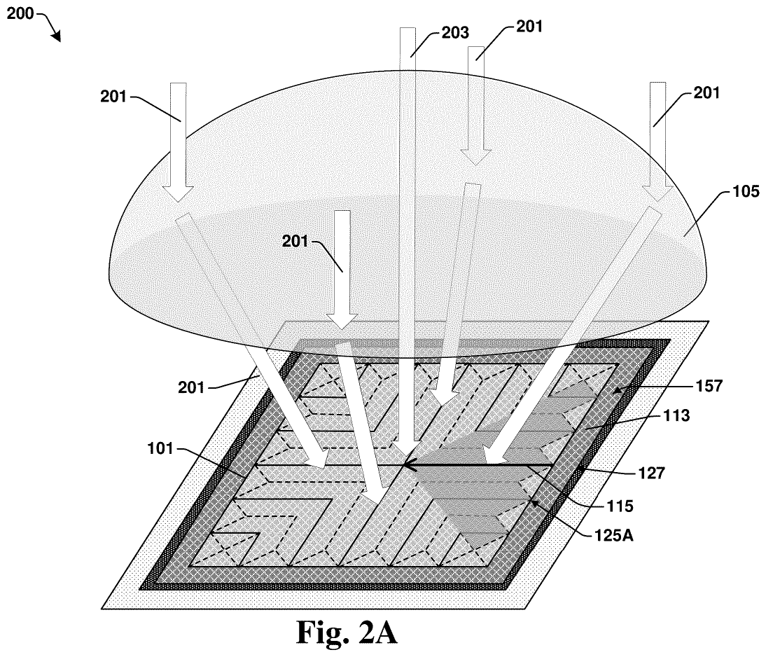

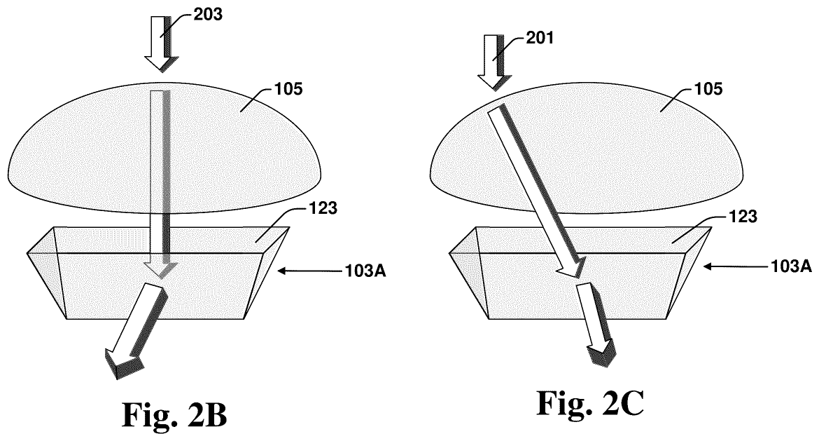

FIGS. 2A-2C illustrate the advantages of the grating and facet orientations described herein. FIG. 2A is a perspective view 200 showing how light entering through the microlens 105 is directed toward the diffuser 107A. As illustrated, light 203 entering near the center of the microlens 105 tends to strike the diffuser 107A at or near normal incidence. In contrast, light 201 entering from the periphery of the microlens is generally refracted inward, toward the center of the diffuser, resulting in oblique angles of incidence. The grating 125A (see FIG. 1A) and other gratings described herein are oriented to extend in approximately the same directions along which the peripheral light 201 is bent, particularly near the midlines 115.

FIG. 2B shows light 203 entering a trench arm 103A at an angle approximately normal to the back side 157 of the semiconductor substrate 113 (see FIG. 1C). The angled facets 123 form V-shaped trench profiles that refract the normally incident light to more oblique paths. This redirection increases the optical path length through the semiconductor substrate 113 and thus improves the likelihood of photon absorption.

FIG. 2C illustrates light 201 that enters a diffuser at an oblique angle due to refraction by the microlens 105. This light 201 travels along a direction approximately aligned with the trench arm 103A. The angled facets 123 interact with the oblique light and diffract it further, but in a direction such that results in the angle remains within a range that promotes absorption. In contrast, if the trench arm 103A were oriented perpendicular to the light path (e.g., rotated by 90 degrees), the same facets would tend to diffract the light to steeper angles, reducing the optical path length and the absorption efficiency.

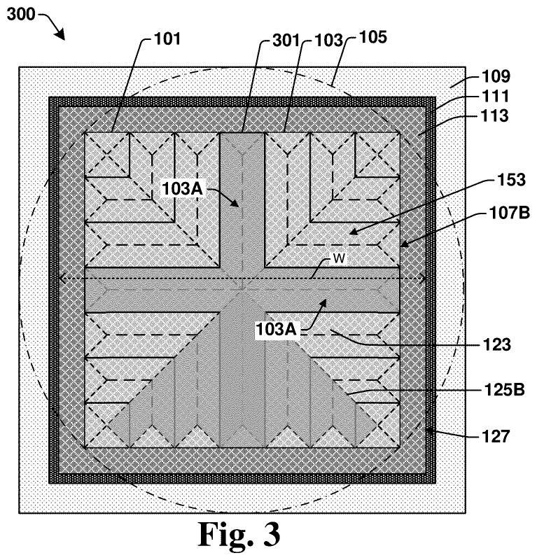

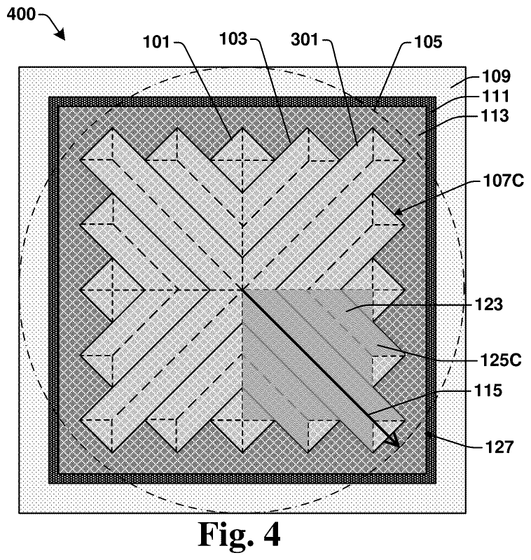

FIG. 3 illustrates a plan view of an image sensor 300 that includes a diffuser 107B. The diffuser 107B comprises four gratings 125B, one of which is shaded and labeled. Each of the gratings 125B includes indentations 153 (see FIG. 1D) formed in the back side 157 of the semiconductor substrate 113. The indentations 153 include four inverted pyramids 101, eight L-shaped trenches 103, and a cross-shaped trench 301, which is also shaded. The cross-shaped trench 301 has a structure similar to that of the L-shaped trenches 103 but includes four trench arms 103A, one extending into each of the four gratings 125B.

In some embodiments, the inverted pyramids 101 and the trench arms 103A of the L-shaped trenches 103 and cross-shaped trench 301 all have equal widths and form periodic gratings. The gratings 125A in FIG. 1A include an even number of indentations (e.g., six), while the gratings 125B in FIG. 3 include an odd number of indentations (e.g., seven). When the indentations are periodically spaced, the cross-shaped trench 301 appears only if the number of indentations in each grating is odd.

In some embodiments, the diffusers 107A and 107B are sized to be as large as, or larger than, the optical spot size formed by the microlens 105 on the back side 157 of the semiconductor substrate (see FIG. 1B). The spot size is typically smaller than the width W of the pixel area 127. In some embodiments, the width W is about 1.4 μm or less. In other embodiments, where the pixels are larger, W may be in the range from about 1.4 μm to about 10.1 μm. Larger pixel sizes are generally more effective for near-infrared (NIR) imaging. NIR wavelengths range from approximately 780 nm to 2500 nm, with 940 nm being a wavelength commonly used to benchmark the diffuser performance.

For NIR imaging, the indentations 153 preferably have depths in the range of approximately 200 nm to 700 nm. The depth is generally about 70% of the pitch. Accordingly, in some embodiments, the pitch of the indentations 153 is in the range of about 280 nm to about 1000 nm. As a result, each grating 125 can contain from 3 to about 35 indentations 153. In some embodiments, each grating includes five or more indentations. In general, the number of indentations contributing to each grating 125 is equal to or greater than the numbers illustrated in the figures. Gratings with smaller numbers of indentations are easier to illustrate.

FIG. 4 illustrates a plan view of an image sensor 400 that includes a diffuser 107C. The diffuser 107C comprises four gratings 125C arranged with 90-degree rotational symmetry about the center of the pixel area 127. Within each grating 125C, the facets 123 are oriented parallel to a respective midline 115. The midlines 115 in this configuration are aligned along the diagonals of the pixel area 127, and each grating 125C occupies one of four square quadrants of the pixel area. By contrast, in FIG. 1A, the gratings 125A have midlines 115 that align with the vertical and horizontal axes (rather than the diagonals), and each grating is distributed within a triangular quadrant of the pixel area 127. This example shows the possibility of varying the grating orientations while keeping the gratings aligned to radians of respective quadrants, and highlights that there are various ways of dividing a pixel area into quadrants.

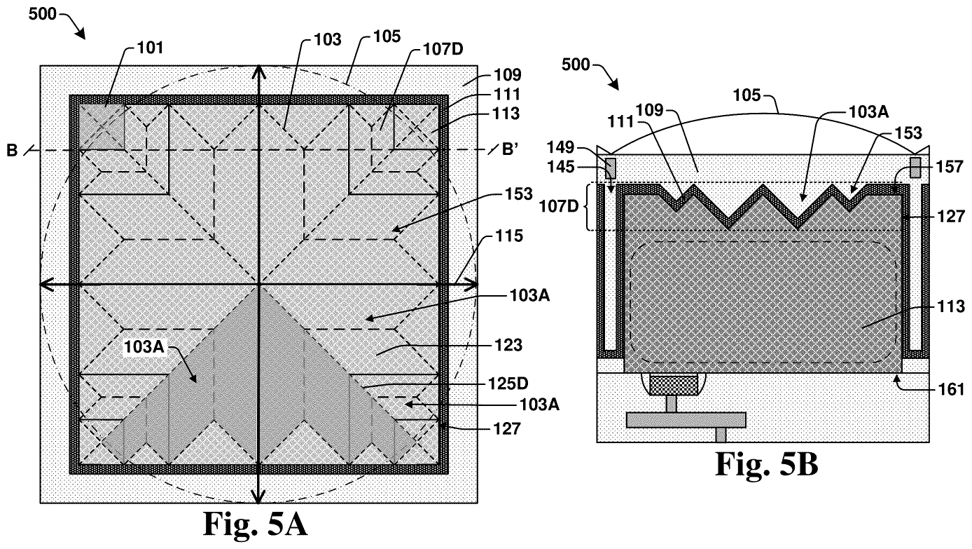

FIG. 5A illustrates a plan view, and FIG. 5B illustrates a cross-sectional view, of an image sensor 500 that includes a diffuser 107D. The cross-sectional view in FIG. 5B is taken along the line B-B′ shown in FIG. 5A. The diffuser 107D comprises four gratings 125D arranged with 90-degree rotational symmetry about the center of the pixel area 127. Unlike the gratings 125A-125C in FIGS. 1A, 3, and 4, which are periodic, the gratings 125D are aperiodic. The gratings 125D are considered gratings in the sense that they contain directional and repetitive features—specifically, groups of facets 123 that are parallel to one another and aligned with the respective midlines 115, thereby defining the grating direction. However, they are aperiodic in that the trench arms 103A located near the midlines 115 are wider than the inverted pyramids 101 and the trench arms 103A located farther from the midlines. As shown in FIG. 5B, the trench arms 103A are also deeper near the center of the diffuser 107D, in proportion to their increased widths. These deeper indentations 153 near the center define a central well that can enhance light trapping and improve absorption efficiency.

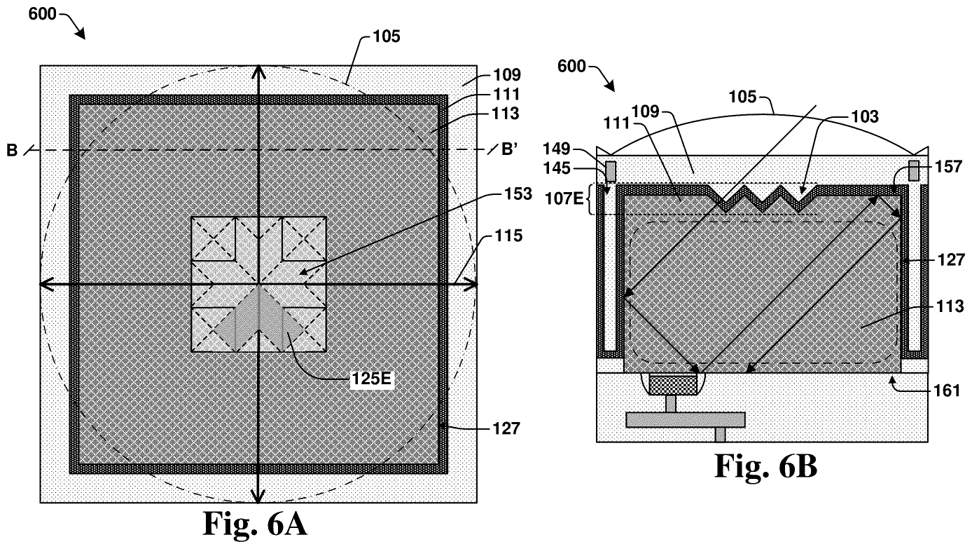

FIG. 6A illustrates a plan view, and FIG. 6B illustrates a cross-sectional view, of an image sensor 600 that includes a diffuser 107E with four gratings 125E. In this embodiment, the diffuser 107E occupies less than one-eighth of the total pixel area 127 and less than one-eighth of the area beneath the microlens 105. As shown in FIG. 6B, confining the diffuser to a small central region relative to the full pixel area can enhance light trapping through internal reflection including reflection off the back side 157 of the semiconductor substrate 113. This light trapping effect increases the likelihood of photon absorption and can thereby improve quantum efficiency.

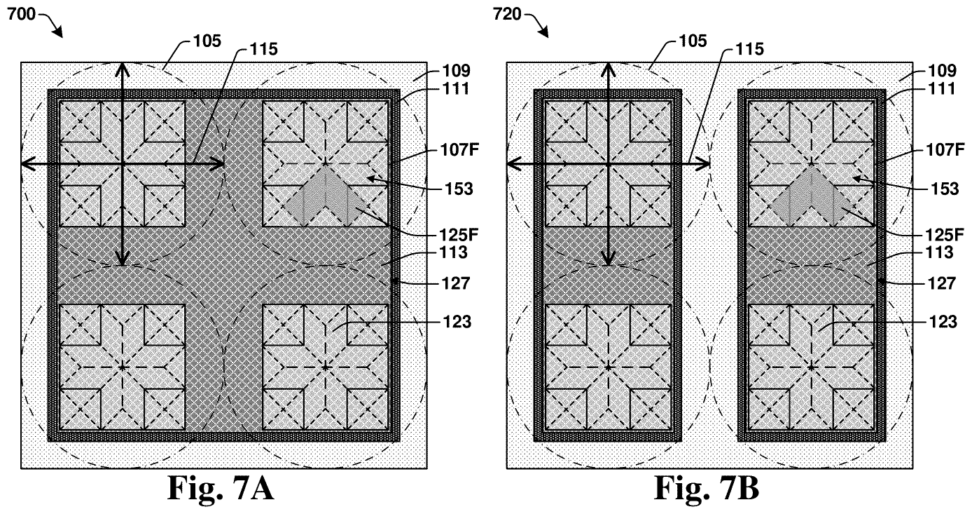

FIGS. 7A and 7B illustrate plan views of image sensors 700 and 720, each comprising diffusers 107F centered beneath microlenses 105. Each diffuser 107F includes four gratings 125F. In the image sensor 700, there are four microlenses 105 for each pixel area 127 and four corresponding diffusers 107F. In the image sensor 720, there are two microlenses 105 for each pixel area 127 and two corresponding diffusers 107F. Providing multiple microlenses 105 for each pixel area 127 can simplify microlens fabrication, particularly for large-pixel designs. When multiple microlenses are used within a single pixel area, each diffuser 107F is centered beneath its respective microlens 105 and is not necessarily located at the center of the pixel area 127. These examples illustrate that the diffusers are centered underneath corresponding microlens, regardless of whether the microlens are centered over the pixel area.

FIG. 8 illustrates a plan view of an image sensor 800 that includes a diffuser 107G. The diffuser 107G is a single, continuous structure that performs the combined function of the four individual diffusers 107F shown in image sensor 700 of FIG. 7. The diffuser 107G includes four sets of four gratings 125G, each set exhibiting 90-degree rotational symmetry and positioned beneath a corresponding microlens 105. Replacing the four separate diffusers 107F with a single integrated diffuser 107G may enhance quantum efficiency by increasing the grating area and may simplify manufacturing.

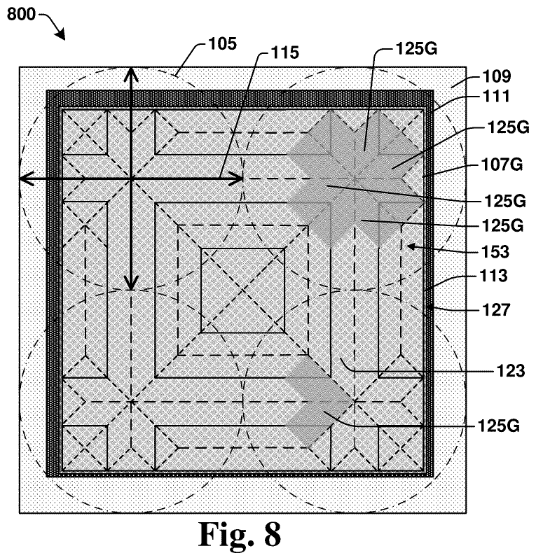

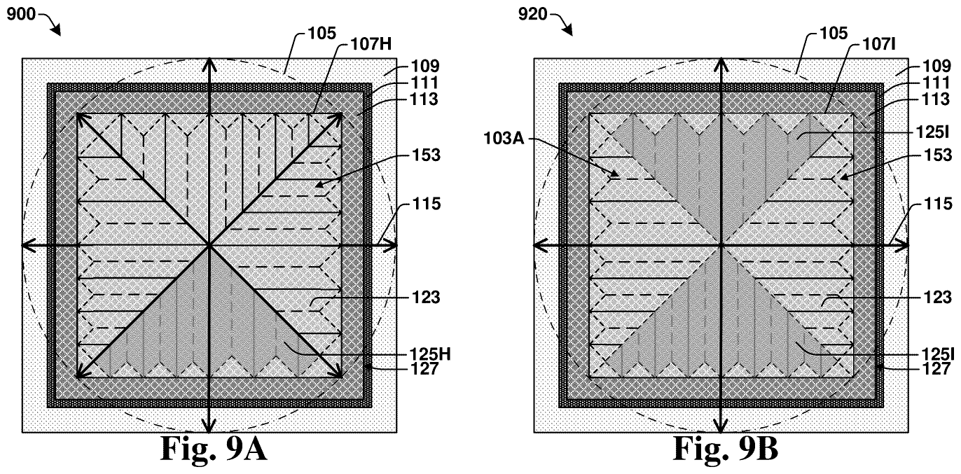

FIGS. 9A and 9B illustrate plan views of image sensors 900 and 920, which include diffusers 107H and 107I, respectively. Like the previously described embodiments, these diffusers include four gratings arranged in four quadrants centered beneath a microlens, with each grating comprising groups of facets 123 that are parallel to a respective midline 115. These examples differ from the previously described embodiments in that they lack some of their symmetries.

The diffuser 107H of FIG. 9A includes four gratings 125H, each occupying one quadrant beneath a microlens. Each grating 125H exhibits mirror symmetry with its adjacent gratings across the radial lines separating the quadrants. However, the grating 125H lack 90-degree rotational symmetry about the central point beneath the microlens 105.

The diffuser 107I of FIG. 9B also includes four quadrant-based gratings 125I. Although each grating is oriented parallel to its respective midline 115, the spacing (periods) of the trench arms 103A varies among the gratings 125I, creating a non-uniformity that breaks symmetry. While 90-degree rotational symmetry arises naturally in diffuser designs according to the guidelines provided herein, the examples in FIGS. 9A and 9B demonstrate that such symmetry is not a necessary condition for achieving improved quantum efficiency. These designs still operate according to the principles illustrated in FIGS. 2A-2C, wherein the orientation of the trench arms 103A and the facets 123 promotes propagation of light at oblique angles that increase optical path lengths and enhance absorption.

FIGS. 10-18 illustrate an image sensor with a diffuser according to the present disclosure at various stages of manufacture according to a process of the present disclosure. Although FIGS. 10-18 are described in relation to a series of acts, it will be appreciated that the order of the acts may in some cases be altered and that this series of acts are applicable to structures other than the ones illustrated. In some embodiments, some of these acts may be omitted in whole or in part. Furthermore, FIGS. 10-18 are described in relation to a series of acts, it will be appreciated that the structures shown in FIGS. 10-18 are not limited to a method of manufacture but rather may stand alone as structures separate from the method.

As shown by the cross-sectional view 1000 of FIG. 10, the method begins with front-end-of-line (FEOL) processing of a semiconductor substrate 113 including processes that form photodiodes 1001, transistors 131, and isolation structures 141 on the front side 161. The semiconductor substrate 113 may be or comprise, for example, a bulk silicon substrate, a silicon-on-insulator (SOI) substrate, or some other suitable semiconductor substrate. In some embodiments, the semiconductor substrate 113 has (100) crystal orientation.

The photodiodes 1001 can be formed with one or more ion implantation (doping) steps. Doping my also form floating diffusion regions, pinning regions, or other such structures used in photodetectors. The isolations structures 141 may be shallow trench isolation structures, the like, or any other suitable type of isolation structure. The transistors 131 may include transfer gates, select gates, reset gates, source followers, or other such transistors used in photodetector pixel circuits. The transistors 131 may be planar transistors, vertical gate transistors, a combination thereof, or any other suitable types of transistors.

As shown by the cross-sectional view 1100 of FIG. 11 the method continues with back-end-of-line (BEOL) processing. BEOL processing forms a metal interconnect structure 139 on the front side 161. The metal interconnect structure 139 include wires 135, vias 1101, and inter-metal dielectric 1103. The wires 135 can be disposed in a plurality of metallization layers interleaved with via layers containing the vias 1101. The wires 135 and the vias 1101 may form metal interconnects that complete photodetector pixel circuits.

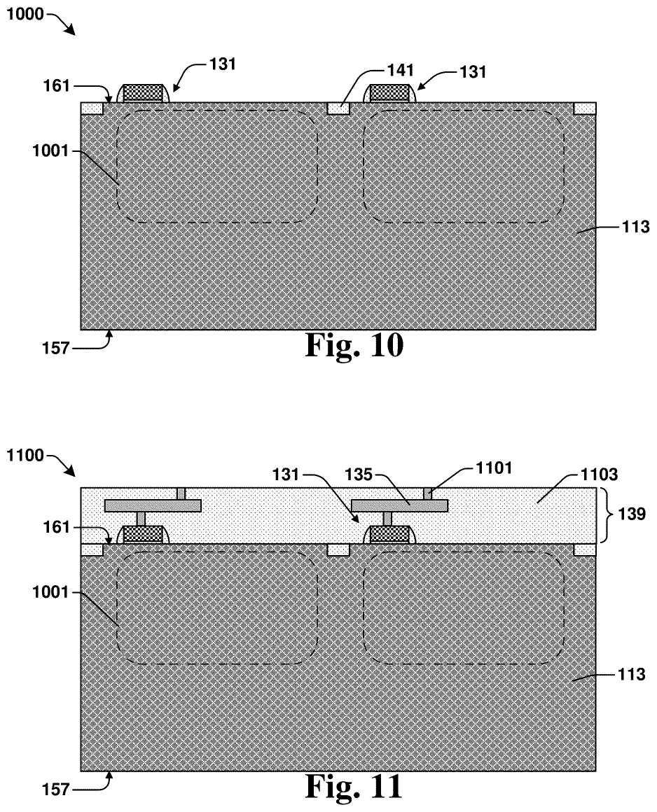

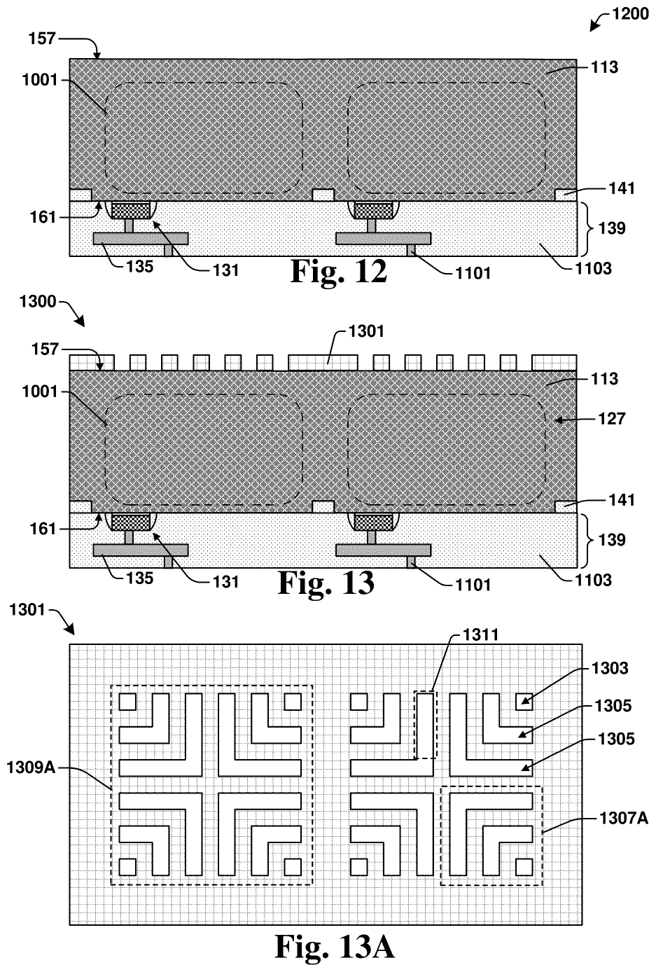

As illustrated by the cross-sectional view 1200 of FIG. 12, the semiconductor substrate 113 is thinned from the back side 157. Prior to thinning, the semiconductor substrate 113 is bonded to another substrate (not shown) that provides mechanical support and/or additional functionality. The other substrate may provide portions of the photodetector pixel circuits, may provide an application specific integrated circuit (ASIC), and may itself be attached to another substrate that provides these or other functionalities.

Typically, the semiconductor substrate 113 begins with a thickness in the range from about 700 μm to about 800 μm. Thinning reduces the semiconductor substrate 113 to a thickness in the range from about 1 μm to about 100 μm. Semiconductor substrates are often reduced to thicknesses below 5 μm for CMOS image sensors with back side illumination. However, it can be advantageous to use a greater thickness to increase NIR absorption. Accordingly, in some embodiments the thickness is kept over 5 μm. In some embodiments, the thickness is left about 10 μm or greater.

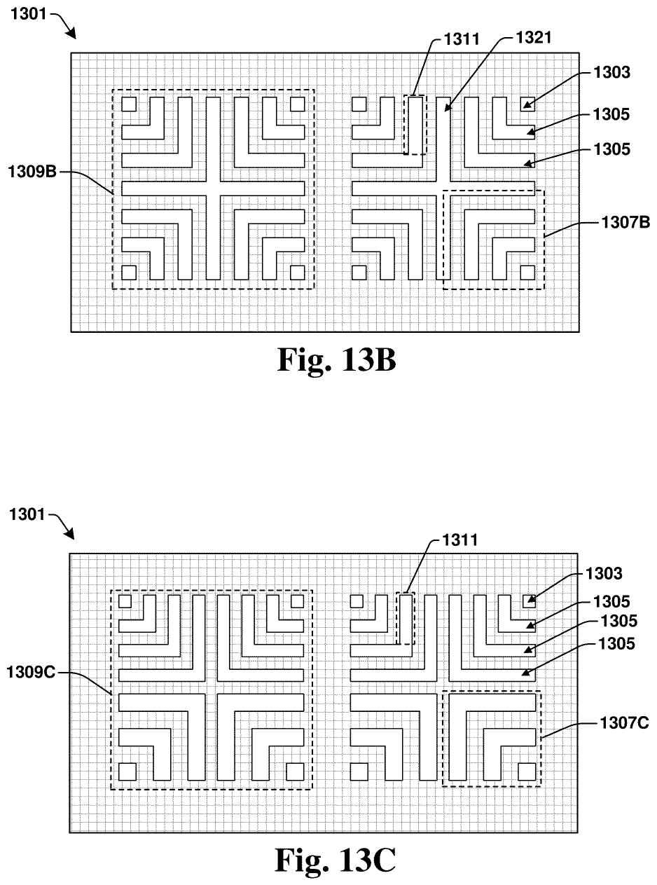

As shown in the cross-sectional view 1300 of FIG. 13, after the thinning process, a mask 1301 is formed on the back side 157 of the semiconductor substrate 113. The mask 1301 may be composed of a photoresist, a hard mask, a combination thereof, or any other suitable material. It may be patterned using photolithography, ion beam lithography, or another appropriate lithographic technique.

FIG. 13A presents a plan view of mask 1301 featuring an opening pattern 1309A according to one embodiment. This pattern is repeated for each photodiode 1001. The opening pattern 1309A includes four sub-patterns 1307A arranged with 90-degree rotational symmetry around a central point. The pattern may consist of square-shaped openings 1303 and L-shaped openings 1305. Each L-shaped opening 1305 forms two slits 1311, each of which is oriented along one of the <110> crystal directions of semiconductor substrate 113. All the slits 1311 in pattern 1309A follow these <110> directions. This pattern may be used to form the diffuser 107A illustrated in FIGS. 1A-1D.

FIG. 13B shows a plan view of mask 1301 with an alternative opening pattern 1309B. In addition to square-shaped openings 1303 and L-shaped openings 1305, this pattern includes a cross-shaped opening 1321. Like the previous embodiment, pattern 1309B is composed of four sub-patterns 1307B exhibiting 90-degree rotational symmetry around a central point. This configuration can be employed to fabricate the diffuser 107B as shown in FIG. 3.

FIG. 13C illustrates another embodiment, showing a plan view of the mask 1301 with opening pattern 1309C. This pattern includes square-shaped openings 1303 and L-shaped openings 1305 arranged into four sub-patterns 1307C. However, unlike the earlier examples, the widths of the square and L-shaped openings vary among the four quadrants. As a result, the sub-patterns 1307C lack the 90-degree rotational symmetry seen in patterns 1309A and 1309B. This variation enables the formation of the diffuser 107I, as depicted in FIG. 9A.

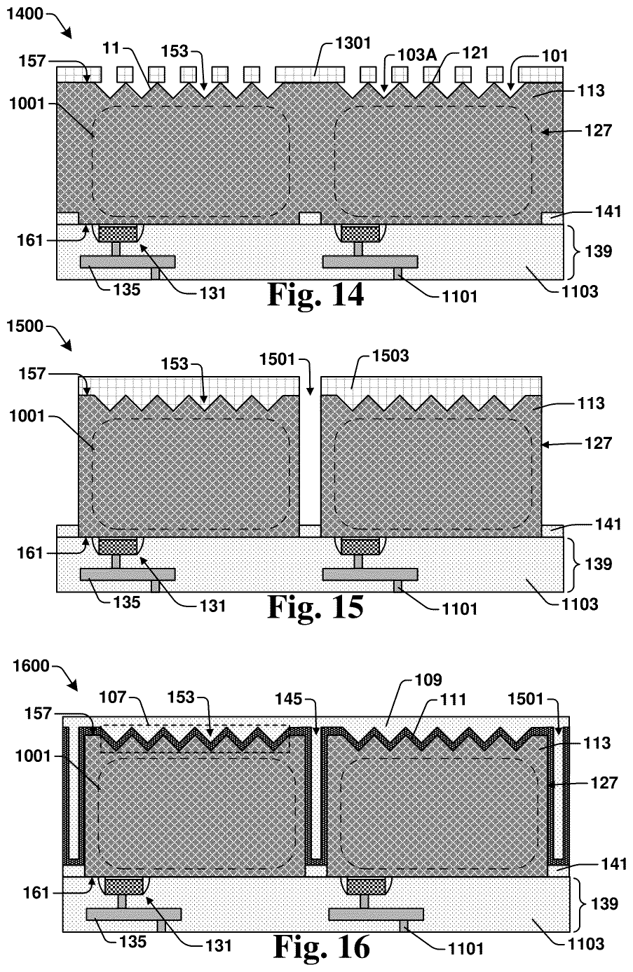

As illustrated by the cross-sectional view 1400 of FIG. 14, the semiconductor substrate 113 is etched through the openings in the mask 1301 to provide indentations 153. The indentations 153 can include trench arms 103A and inverted pyramids 101. The etch process is selected to provide the openings with angled sidewalls, which are the facets 123. Angled sidewalls may alternatively be formed with anisotropic dry etching, however, in some embodiments, the etch process is an anisotropic wet etch.

Anisotropic wet etching may use an alkaline solution such as potassium hydroxide (KOH), tetramethylammonium hydroxide (TMAH), or the like that provides different etch rates for different crystallographic planes in silicon. In particular, these alkaline solutions provide

much faster etch rates in the [symbol] 100 [symbol] and [symbol] 110 [symbol] crystal directions than in the [symbol] 111 [symbol] crystal direction. The etch rate ratio can exceed 100:1. This type of etch process naturally produces inverted pyramids and trenches with V-shaped profiles. The V-shaped profiles have depth to width ratios of approximately 0.7.

In some embodiments, the etch process is allowed to progress and undercut the mask 1301 until adjacent trenches meet at V-shaped peaks 121. If the mask openings are too widely spaced, or if the etch process is stopped prematurely, mesas may remain between adjacent trenches. Leaving these mesas would reduce efficiency of the resulting diffuser. After etching, the mask 1301 can be stripped.

As shown by the cross-sectional view 1500 of FIG. 15, a mask 1503 is formed and used to etch deep trenches 1501 into the back side 157. Etching of the deep trenches 1501 may stop on the shallow trench isolation structures 141. Alternatively, the deep trenches 1501 may be made to otherwise stop short of the front side 161, may extend to the front side 161, or may stop on metal pads within the metal interconnect structure 139. The deep trenches 1501 form a grid within one photodiode 1001 in each cell. The cells correspond to photodetector pixel areas 127.

The cross-sectional view 1600 of FIG. 16 illustrates the deposition of a medium refractive index dielectric layer 111 and a low refractive index dielectric layer 109 to simultaneously fill the deep trenches 1501 to create the BDTI structure 145 and fill the indentations 153 to complete the formation of the diffuser 107. The low refractive index dielectric layer 109 is typically silicon dioxide (SiO₂) or the like. The medium refractive index dielectric layer 111 may be operative as an antireflective coating. The medium refractive index dielectric layer 111 may comprise one or more layers of tantalum oxide (Ta₂O5), titanium oxide (TiO₂), silicon nitride (Si₃N₄), silicon oxynitride (SiON), aluminum oxide (Al₂O₃), hafnium oxide (HfO₂), zirconium oxide (ZrO₂), combinations thereof or the like. These layers can be deposited by atomic layer deposition (ALD), physical vapor deposition (PVD), chemical vapor deposition (CVD), the like, or any other suitable process.

Simultaneously filling the deep trenches 1501 to create the BDTI structure 145 to fill the indentations 153 to complete the formation of the diffuser 107 has the advantage of reducing the total number of processing steps, but it will be appreciated that these processes may be separated in whole or in part to provide different compositions to create the BDTI structures 145 and to fill the indentations 153 of the diffuser 107. For example, it can be desirable to line the deep trenches 1501 with one or more layers of dielectrics that exhibit fixed negative charges. Examples of such dielectrics include hafnium oxide (HfO₂), aluminum oxide (AlO), and the like. It may or may not be desirable to have these same materials at the semiconductor interface in the diffuser 107.

In some embodiments, the BDTI structures 145 include a metal core (not shown). Providing the BDTI structures 145 with a metal core comprises lining the deep trenches 1501 with dielectric and then filling the deep trenches 1501 with a metal. Excess metal may be removed from over the back side 157 by chemical mechanical polishing (CMP). The deep trenches 1501 may be lined while simultaneously filling the indentations 153. In an alternative embodiment, the indentations 153 are formed after the BDTI structures 145, enabling the diffuser 107 to be made with entirely different dielectric thickness or compositions from those used in the deep trenches 1501.

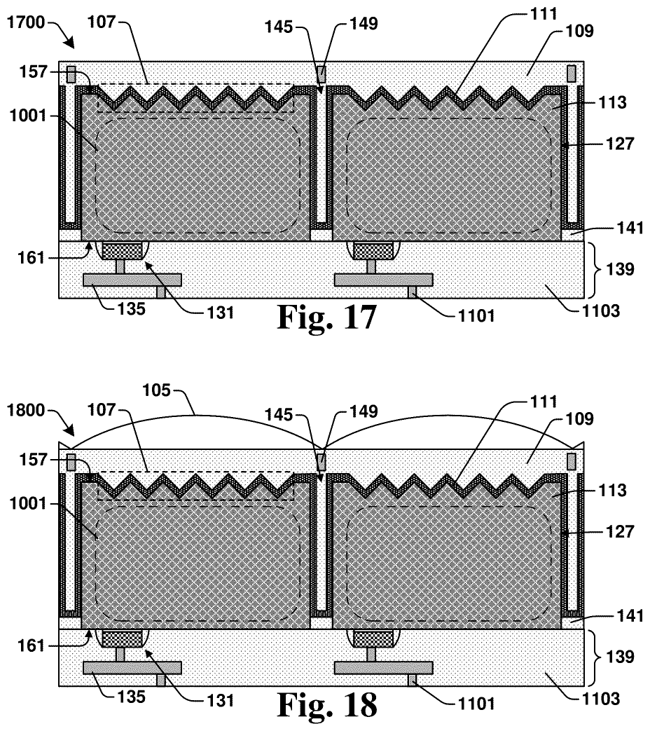

As shown by the cross-sectional view 1700 of FIG. 17, additional passivation layers and other structures may be formed on the back side 157 over the diffusers 107. These may include a back side metal grid 149 and color filters (not shown). The back side metal grid 149 may be formed by depositing and etching a composite grid stack including hard mask, metal, and dielectric layers. Color filters may be formed by filling the cells of the composite grid with suitable materials.

As shown by the cross-sectional view 1800 of FIG. 18, microlens 105 are formed over the pixel areas 127 and the diffusers 107. The microlens 105 are centered over diffusers 107. There may be one microlens 105 for each of the diffusers 107. The microlenses 105 may be formed of dielectric, polymer, the like, or any other suitable material and may be formed by any suitable process. The process of forming the microlenses 105 may include, for example, deposition of the lens material followed by etching to define the lens shapes. In some embodiments, the formation process includes a thermal reflow process or the like.

The microlens 105 may have any suitable focal point. In some embodiments, the focal point is at the back side 157. This may provide the highest quantum efficiency for an ideal lens. In some embodiments, the focal point is within the semiconductor substrate 113 below the back side 157. This design may be less sensitive to manufacturing variations and may provide the highest quantum efficiency as a practical matter.

Some aspects of the present disclosure relate to a diffuser in an image sensor. The image sensor is of the type that has a photodiode in a semiconductor substrate, a metal interconnect structure disposed on the front side, and a microlens disposed on the back side. The diffuser is on the back side between the microlens and the photodiode. The diffuser is centered beneath the microlens and comprises four gratings formed by indentations in the back side. The gratings are arranged with 90-degree rotational symmetry about a central point.

In some embodiments, the semiconductor substrate has (100) crystal orientation, and the grating are aligned with <110> crystal directions. In some embodiments, the indentations have openings that are either cross-shaped, L-shaped, or square-shaped and have slanted sidewalls such that they become narrower with increasing depth into the semiconductor substate. In some embodiments, the indentations with openings that are cross-shaped or L-shaped comprise trenches with V-shaped profiles and the indentations with openings that are square-shaped form inverted pyramids. In some embodiments, the diffuser comprises four of the inverted pyramids.

In some embodiments, two of the indentations are laterally adjacent and have openings that meet at a V-shaped peak. In some embodiments, the openings are either L-shaped or square-shaped. In some embodiments, the one of the openings is cross-shaped. In some embodiments, the openings all have equal widths. In some embodiments, the each of the four gratings is symmetrical about its respective midline and the indentations closest to the midlines are deeper and wider than the indentations furthest from the midlines. In some embodiments, the photodiode is within a pixel area bordered by an isolation structure that extends into the semiconductor substrate, and the diffuser occupies less than half the pixel area.

Some aspects of the present disclosure relate to a diffuser in an image sensor. The image sensor is of the type that has a photodiode in a semiconductor substrate, a metal interconnect structure disposed on the front side, and a microlens disposed on the back side. The diffuser comprises indentations in the back side. The diffuser is divisible into four quadrants centered under the microlens, each of the quadrants having a midline, and each quadrant comprising a grating having a plurality of first planar surfaces in distinct planes, parallel to one another, and parallel to the respective midline.

In some embodiments, each of the gratings comprises one or more trenches extending parallel to the respective midline. In some embodiments, the plurality of first planar surfaces in distinct planes comprise first planar surfaces in at least three distinct planes. In some embodiments, each grating has mirror symmetry with the gratings in each adjoining quadrant. In some embodiments, each grating comprises a plurality of second planar surfaces in distinct planes, parallel to one another, and parallel to the respective midline, wherein the second planar surfaces have a distinct orientation from the first plurality of planar surfaces. In some embodiments, the first planar surfaces and the second planar surfaces form sidewalls of trenches that extend parallel to the respective midline.

Some aspects of the present disclosure relate to a method of manufacturing an image sensor. The method includes forming a photodiode within a semiconductor substrate, forming a metal interconnect structure over the front of the semiconductor substrate, bonding the semiconductor substrate to a second substrate, thinning the semiconductor substrate from the second side, forming a mask over the second side, etching through the mask with an anisotropic wet etch process to form a pattern of indentations in the second side, depositing a first dielectric within the indentations, wherein the first dielectric has a lower index of refraction than the semiconductor substrate and forming a microlens over the second side and centered over the pattern of indentations. The mask has a pattern of openings that is a composite of four sub-patterns arranged with 90-degree rotational symmetry about a central point, and the pattern of openings comprises L-shaped openings.

In some embodiments, the semiconductor substrate has (100) crystal orientation, and the L-shaped opening has arms extending along <110> crystal directions. In some embodiments, the method further comprising etching deep trenches in the second side, wherein depositing the first dielectric within the indentations deposits the first dielectric within the deep trenches.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor, comprising:
a substrate having a first side and a second side opposite the first side across a thickness of the substrate;
a microlens disposed on the second side; and
a diffuser comprising indentations in the second side, wherein the diffuser is between the microlens and the substrate and is divisible into four quadrants, each quadrant comprising a grating having a plurality of first planar surfaces in distinct planes, parallel to one another, and each grating having the same orientation as the grating in the opposite quadrant, and a distinct orientation from the gratings in the adjacent quadrants.

2. The image sensor of claim 1, wherein the substrate has (100) crystal orientation, and the grating are aligned with <110> crystal directions.

3. The image sensor of claim 1, wherein the indentations have openings that are either cross-shaped, L-shaped, or square-shaped and have slanted sidewalls such that they become narrower with increasing depth into the substrate.

4. The image sensor of claim 1, wherein the indentations comprise four inverted pyramids.

5. The image sensor of claim 3, wherein two of the indentations are laterally adjacent and have openings that meet at a V-shaped peak.

6. The image sensor of claim 3, wherein the openings have equal widths.

7. The image sensor of claim 1, wherein each of the four gratings is symmetrical about its respective midline and the indentations closest to the midlines are deeper and wider than the indentations furthest from the midlines.

8. The image sensor of claim 1, wherein the diffuser is disposed over a photodiode within the substrate.

9. The image sensor of claim 1, wherein the plurality of first planar surfaces in distinct planes comprise first planar surfaces in at least three distinct planes.

10. The image sensor of claim 1, wherein each of the gratings has a plurality of second planar surfaces that are in distinct planes and parallel to one another, and the first planar surfaces and the second planar surfaces form sidewalls of trenches.

11. The image sensor of claim 1, further comprising:
a photodiode within the substrate, wherein the substrate is a semiconductor substrate and the photodiode is within a pixel area of the semiconductor substrate; and
an isolation structure wherein the isolation structure extends into the semiconductor substrate, borders the pixel area;
wherein the diffuser occupies less than half the pixel area.

12. A method of manufacturing an image sensor, the method comprising:
providing a substrate having a first side and a second side opposite the first side across a thickness of the substrate;
forming a mask over the second side, wherein the mask has a pattern of openings that is a composite of four sub-patterns arranged with 90-degree rotational symmetry, and the pattern of openings comprises L-shaped openings;
etching through the mask with an anisotropic wet etch process to form a pattern of indentations in the second side; and
depositing a first dielectric within the indentations, wherein the first dielectric has a lower index of refraction than the substrate.

13. The method of claim 12, further comprising forming a microlens over the pattern of indentations.

14. The method of claim 13, further comprising:
forming a metal interconnect structure over the first side;
bonding the substrate to a second substrate; and
thinning the substrate from the second side.

15. The method of claim 12, wherein the substrate is a semiconductor substrate having (100) crystal orientation, and the L-shaped opening has arms extending along <110> crystal directions.

16. The method of claim 12, further comprising etching deep trenches in the second side, wherein depositing the first dielectric within the indentations deposits the first dielectric within the deep trenches.

17. A method of manufacturing an image sensor, the method comprising:
providing a substrate having a first side and a second side opposite the first side across a thickness of the substrate;
forming a mask over the second side, wherein the mask has a pattern of openings that is divisible into four quadrants, each of the quadrants having each quadrant comprising a plurality of parallel slits, the slits in opposite quadrants having the same orientation, and the slits in adjacent quadrants having distinct orientations;
etching through the mask with an anisotropic wet etch process to form a pattern of indentations in the second side; and
depositing a first dielectric within the indentations, wherein the first dielectric has a lower index of refraction than the substrate.

18. The method of claim 17, wherein the substrate is a semiconductor substrate having (100) crystal orientation, and the slits extend along <110> crystal directions.

19. The method of claim 17, wherein slits in adjacent quadrants meet to form L-shaped openings.

20. The method of claim 17, further comprising:
forming a photodiode by implanting dopants in the first side;
forming a metal interconnect structure over the first side;
bonding the substrate to a second substrate;
thinning the substrate from the second side; and
forming a microlens over the pattern of indentations.
